(19) United States
(12) Patent Application Publication
(10) Pub. No.: US 2007/0224758 A1
(43) Pub. Date: Sep. 27, 2007

(54) Semiconductor memory device and related fabrication method

(76) Inventor: Jeong-Ju Park, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/516,750

(22) Filed: Sep. 7, 2006

(30) Foreign Application Priority Data
Mar. 23, 2006 (KR) 2006-0026327

(51) Int. Cl. H01L 21/8242

(52) U.S. Cl. 438/253

(57) ABSTRACT

Embodiments of the invention provide a semiconductor memory device and a method for fabricating the semiconductor memory device. The semiconductor memory device comprises a source region and a drain region disposed in a semiconductor substrate; a buried contact disposed on and electrically connected to the source region of the transistor; and a direct contact disposed on and electrically connected to the drain region of the transistor, wherein an upper surface of the direct contact is disposed at a different height than an upper surface of the buried contact. The semiconductor memory device further comprises a bit line disposed on and electrically connected to the direct contact and thereby electrically connected to the drain region; and a lower electrode of a capacitor disposed on and electrically connected to the buried contact and thereby electrically connected to the source region.

### BACKGROUND

1. Field of the Invention

Embodiments of the invention relate to a semiconductor memory device and a related fabrication method. In particular, embodiments of the invention relate to a semiconductor device comprising contacts formed on source and drain regions, and a method for fabricating the semiconductor device.

This application claims priority to Korean Patent Application No. 10-2006-26327, filed on Mar. 23, 2006, the subject matter of which is hereby incorporated by reference in its entirety.

2. Discussion of Related Art

Semiconductor memory devices may be divided into volatile memory devices and non-volatile memory devices. Volatile memory devices, such as DRAM (Dynamic Random Access Memory) and SRAM (Static Random Access Memory), are able to transmit data relatively rapidly. However, volatile memory devices lose stored data when power is interrupted. In contrast, non-volatile memory devices, such as EPROM (Erasable Programmable Read Only Memory) or EEPROM (Electrically Erasable Programmable Read Only Memory), transmit data relatively slowly, but retain data even when power is interrupted.

DRAM typically comprises a pass transistor and a capacitor. Collectively, the transistor and capacitor form a memory cell. The pass transistor functions as a switch—inputting and outputting electrical charge to the capacitor. The presence or absence of electrical charge on the capacitor is indicative of binary data value. Thus, DRAM's ability to store data depends on the capacitance of the capacitor. Insufficient capacitance has a significantly negative impact on read operations directed to data stored in a memory cell, increasing the read error rate for the DRAM, and making it difficult to operate the DRAM at low voltages. Insufficient capacitance and its attendant results cause a relatively high amount of power to be consumed during the operation of the DRAM.

That is, in order to prevent data errors from occurring due to insufficient capacitance, the DRAM must perform refresh operations that periodically reload electrical charge into memory cells after a predetermined amount of time has lapsed. The rate at which refresh operations are executed depends upon the capacitance of the capacitors in the DRAM device. Hence, an increase in the capacitance of the respective capacitors corresponds to a decrease in the rate at which refresh operations are executed (i.e., an increase in capacitance extends the amount of time for which a capacitor can retain data and improves data input/output in the DRAM device).

In addition, the development of information transmission technology and the growth in the popularity of electronic devices such as computers has fueled dramatic developments in semiconductor device technology. Currently, relatively fast operational speeds, relatively large capacitances for the capacitors, and increasing the degree of integration are required in semiconductor devices. In addition, as the degree of integration of a semiconductor device increases and the capacitance of capacitors in semiconductor devices increases, the amount of area occupied by each pattern formed in a memory device decreases.

As the sizes of patterns in semiconductor devices decrease, the widths of and intervals between wirings in semiconductor devices decrease greatly. Specifically, contacts, which electrically connect to regions formed in the semiconductor substrate, require large alignment margins and isolation margins in a semiconductor device. Thus, when patterns need to be formed in areas smaller than a design rule and there is a repetition of the same pattern, a self-alignment method is used to form contacts such that the contacts each occupy a relatively small region of the semiconductor memory device.

The self-alignment method is a method for forming a pattern using a step difference between elements. In the self-alignment method, contacts of various sizes may be formed in accordance with the height of peripheral structures, the depths of insulation layers in which contacts are formed, etching methods, etc. Thus, the self-alignment method is actively used to form a direct contact that connects a drain region to a bit line, and a buried contact that connects a source region to a lower electrode of a capacitor.

FIG. (FIG.) 1 is a cross-sectional view of a conventional DRAM device.

Referring to FIG. 1, a buried contact 12 and a direct contact 14 are formed on a semiconductor substrate 10. Buried contact 12 makes contact with a source region 22 of a transistor, and direct contact 14 makes contact with a drain region 21 of the transistor. In addition, a bit line 16 surrounded by spacer insulation layers 18 and 20 is formed on direct contact 14. Also, a capacitor (not shown) comprising a plate electrode, a dielectric layer, and a storage electrode is formed on buried contact 12.

As shown in FIG. 1, when fabricating the conventional DRAM device, a lower bit line 16a having a relatively narrow width is formed on direct contact 14, and an upper bit line 16b, which has a larger width than lower bit line 16a, is then formed to somewhat mitigate the restrictions of contemporary design rules.

However, as the degree of integration of the conventional DRAM device increases, a margin between patterns formed through photoetching decreases and will eventually becomes insufficient, so there is a relatively high probability that a misalignment will occur between patterns. For example, when, as shown in FIG. 1, bit line 16 comprises lower bit line 16a and upper bit line 16b, there is a relatively high probability that defects will occur in the conventional DRAM device as a result of a misalignment in patterns disposed in an area indicated by a reference symbol “A”. For example, when lower bit line 16a is patterned such that its width increases towards the working surface of semiconductor substrate 10, and thus a lower portion of lower bit line 16a is disposed relatively nearer buried contact 12 than lower bit line 16a as illustrated in FIG. 1 (i.e., lower bit line 16a is inclined towards buried contact 12), a short circuit may occur between bit line 16 and buried contact 12.

In addition, when buried contact 12 and direct contact 14 are patterned such that they are relatively near one another, a bridge is formed between buried contact 12 and direct contact 14, which causes a short circuit. When bit line 16, which is a signal transmission line adapted to transmit data of a memory cell, is misaligned with respect to direct contact 14, or a short circuit occurs between bit line 16 and an adjacent buried contact 12, the corresponding DRAM cell does not operate normally. In addition, when a bridge occurs between buried contact 12 and direct contact 14, the corresponding DRAM cell will also fail to operate normally.

### SUMMARY OF THE INVENTION

Embodiments of the invention provide a semiconductor memory device adapted to substantially prevent an electrical short circuit from occurring between a bit line and a buried contact of a semiconductor memory device, and adapted to substantially prevent a bridge from being formed between a buried contact and a direct contact of the semiconductor memory device; and a method for fabricating the semiconductor memory device. Embodiments of the invention provide a semiconductor memory device adapted to substantially prevent the deterioration of electric characteristics of a DRAM device, and a method for fabricating the semiconductor memory device.

In one embodiment, the invention provides a semiconductor memory device comprising a source region and a drain region disposed in a semiconductor substrate; a buried contact disposed on and electrically connected to the source region of the transistor; and a direct contact disposed on and electrically connected to the drain region of the transistor, wherein an upper surface of the direct contact is disposed at a different height than an upper surface of the buried contact. The semiconductor memory device further comprises a bit line disposed on and electrically connected to the direct contact and thereby electrically connected to the drain region; and a lower electrode of a capacitor disposed on and electrically connected to the buried contact and thereby electrically connected to the source region.

In another embodiment, the invention provides a method for fabricating a semiconductor memory device comprising forming a source region and a drain region in a semiconductor substrate; depositing a first interlayer insulation layer on the semiconductor substrate after forming the source and drain regions; and forming plurality of contact holes comprising a buried contact hole and a direct contact hole in the first interlayer insulation layer, wherein the buried contact hole exposes the source region and the direct contact hole exposes the drain region. The method further comprises filling the contact holes with a first conductive material to form a buried contact electrically connected to the source region and a direct contact electrically connected to the drain region; selectively etching the direct contact to reduce the height of an upper surface of the direct contact and to thereby form an opening; and forming a spacer on a sidewall of the opening. The method still further comprises filling the opening with at least one second conductive material; patterning the at least one second conductive material to form a bit line connected to the drain region through the direct contact, wherein the spacer is adapted to insulate the bit line from a peripheral region; depositing a second interlayer insulation layer on the semiconductor substrate after forming the bit line; and forming a lower electrode of a capacitor on the semiconductor substrate, wherein the lower electrode of the capacitor is electrically connected to the source region through the buried contact.

In yet another embodiment, the invention provides a method for fabricating a semiconductor memory device comprising forming a source region and a drain region in a semiconductor substrate; depositing a first interlayer insulation layer on the semiconductor substrate after forming the source and drain regions; and forming a plurality of contact holes comprising a buried contact hole and a direct contact hole in the interlayer insulation layer, wherein the buried contact hole exposes the source region and the direct contact hole exposes the drain region. The method further comprises filling the contact holes with a first conductive material to form a buried contact electrically connected to the source region and a direct contact electrically connected to the drain region; selectively etching the buried contact to reduce the height of an upper surface of the buried contact and to thereby form an opening, wherein an upper surface of the direct contact is disposed higher than the upper surface of the buried contact after selectively etching the buried contact; and forming a spacer on a sidewall of the opening. The method still further comprises forming a bit line on and electrically connected to the direct contact and thereby electrically connecting the bit line to the drain region; depositing a second interlayer insulation layer on the semiconductor substrate after forming the bit line; and forming a lower electrode of a capacitor on the semiconductor substrate, wherein the lower electrode of the capacitor is electrically connected to the source region through the buried contact, and the spacer is adapted to insulate the lower electrode of the capacitor from a peripheral region.

### BRIEF DESCRIPTION OF THE DRAWINGS

Embodiments of the invention will be described herein with reference to the accompanying drawings, in which like reference symbols refer to like elements throughout. In the drawings:

FIG. 1 is a cross-sectional view of a conventional DRAM device;

FIG. 2 is a cross-sectional view of a semiconductor memory device in accordance with an embodiment of the invention;

FIGS. 3A through 3F illustrate stages in a method for fabricating the semiconductor memory device of FIG. 2 in accordance with an embodiment of the invention; and,

FIGS. 4A through 4D illustrate stages in a method for fabricating a semiconductor memory device in accordance with another embodiment of the invention.

### DESCRIPTION OF EMBODIMENTS

Though a plurality of the same element may be shown in the drawings, for convenience of description, only one of each element illustrated in a drawing will generally be described with reference to that drawing. In addition, the terms “first”, “second”, etc., are used herein merely for convenience of description.

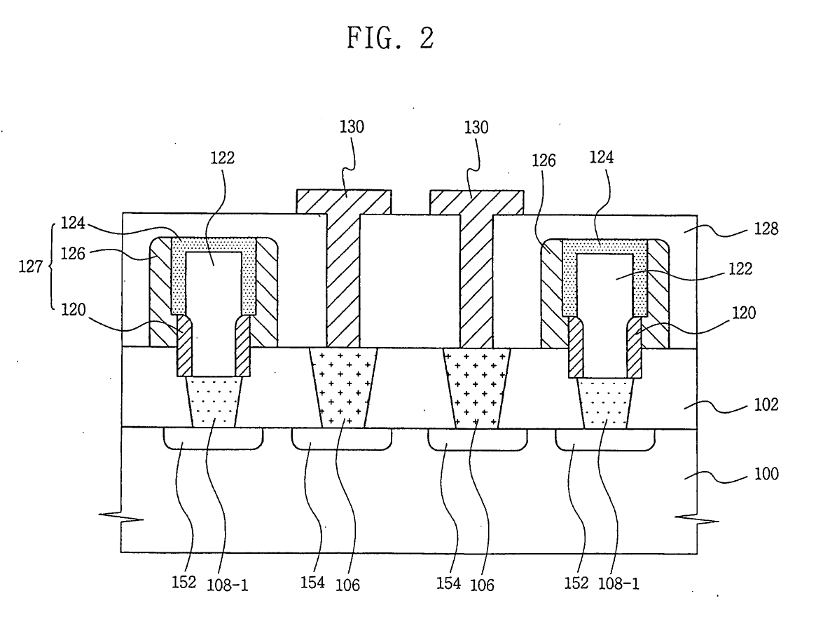

FIG. 2 is a cross-sectional view of a semiconductor memory device in accordance with an embodiment of the invention. Referring to FIG. 2, a buried contact 106 and a direct contact 108-1 are formed on a semiconductor substrate 100 comprising a transistor that comprises a gate region, a source region 154, and a drain region 152. Buried contact 106 makes contact with source region 154 of the transistor, and direct contact 108-1 makes contact with drain region 152 of the transistor. The illustrations of source and drain regions in the drawings are schematic in nature and do not necessarily represent the actual shapes of these regions. In addition, as used herein, when a first element is said to be “on” a second element, the first element may be directly on the second element, or intervening elements may be present.

In addition, a bit line 122 surrounded by an outer insulation layer 127 comprising a spacer 120 and first and second insulation layers 124 and 126 is formed on direct contact 108-1. Outer insulation layer 127 is adapted to insulate bit line 122 from a peripheral region that may comprise buried contact 106 or lower electrode of a capacitor 130. In addition, spacer 120 is disposed adjacent to a lower sidewall of bit line 122; first insulation layer 124 is disposed on spacer 120 and is disposed adjacent to an upper sidewall of bit line 122; and second insulation layer 126 is disposed adjacent to a sidewall of first insulation layer 124 and is disposed adjacent to a portion of a sidewall of spacer 120. A lower electrode of a capacitor 130 is formed on buried contact 106.

As shown in FIG. 2, direct contact 108-1 is formed such that an upper surface of direct contact 108-1 is disposed lower than an upper surface of buried contact 106. A method for forming direct contact 108-1 such that the upper surface of direct contact 108-1 is lower than the upper surface of buried contact 106 as above can reduce the frequency with which a bridge is formed between direct contact 108-1 and buried contact 106. In addition, bit line 122 is formed on direct contact 108-1 through one photoetching process to simplify the process for fabricating the semiconductor memory device of FIG. 2 relative to the process for fabricating the conventional DRAM device, and to form bit line 122 having a corresponding misalignment margin adapted to substantially prevent (for some amounts of misalignment) the misalignment that may exist after forming bit line 122 from causing electrical short circuits between bit line 122 and a peripheral region (which may comprise buried contact 106 and lower electrode 130 of the capacitor).

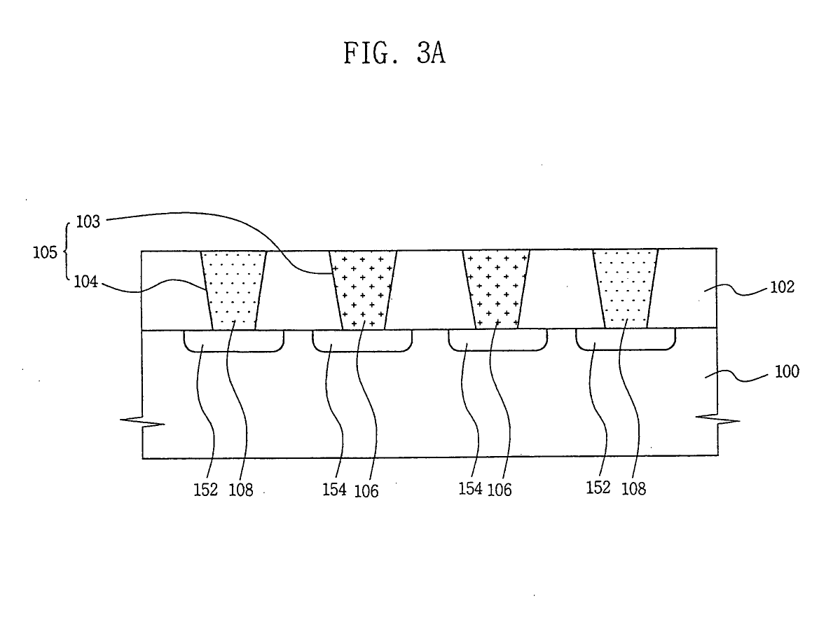

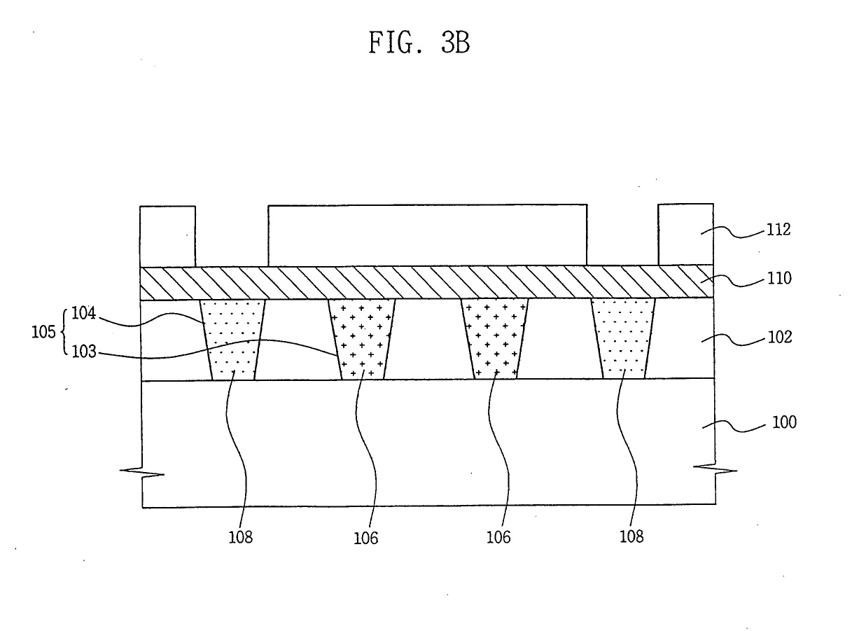

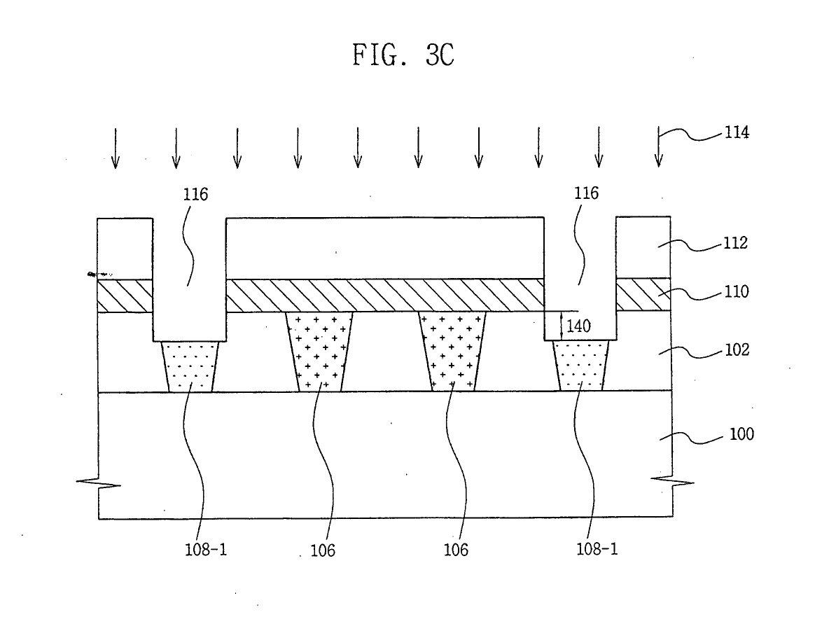

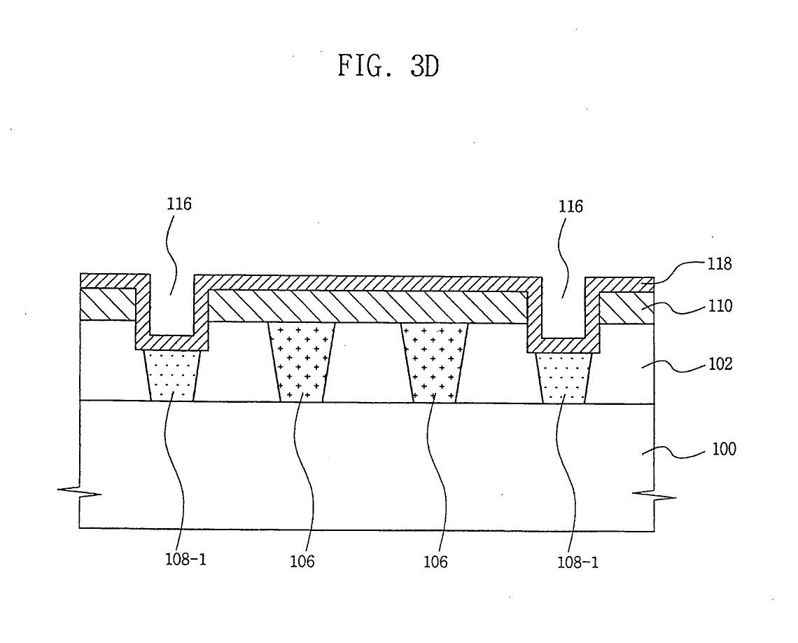

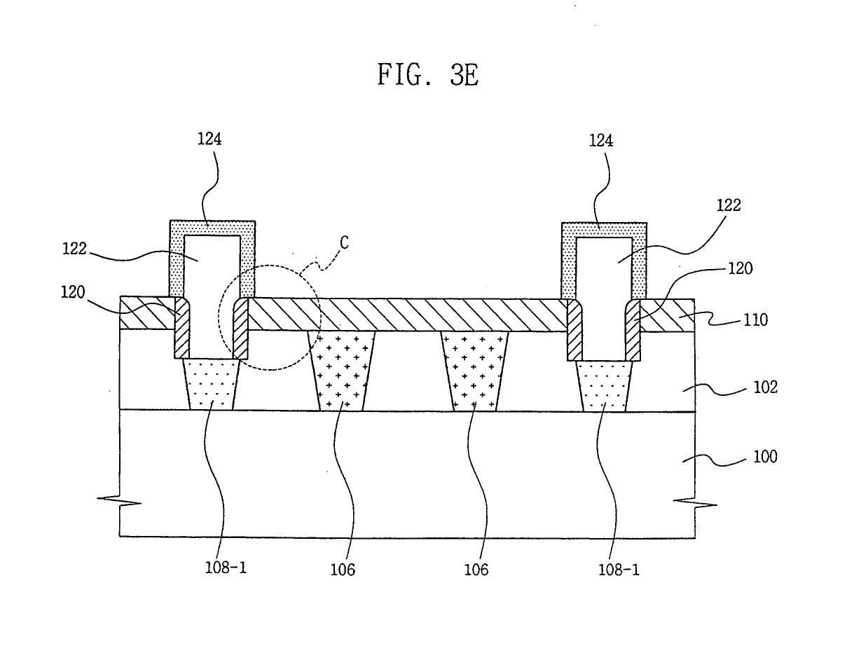

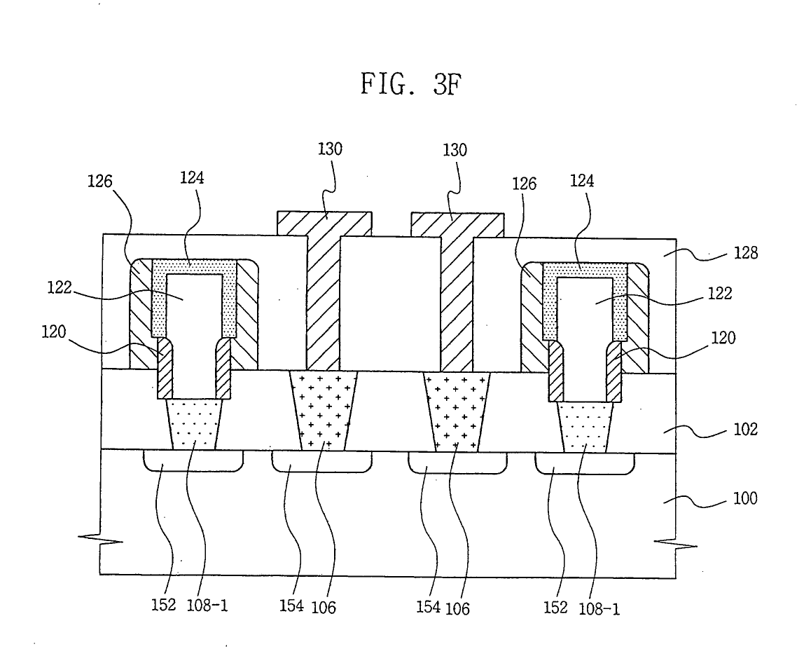

A method for fabricating the semiconductor memory device of FIG. 2, in accordance with an embodiment of the invention, will be described in sequence with reference to FIGS. 3A through 3F.

Referring first to FIG. 3A, a device isolation layer such as shallow trench isolation (STI) is formed in a P-type (or N-type) semiconductor substrate 100 to define a field region and an active region. In order to form a transistor on the active region, a gate oxide layer, a conductive layer (such as a polysilicon), and a spacer are formed in turn in order to form a typical gate region. In addition, impurity ions of Group IIIA (e.g., boron (B)) or Group VA (e.g., phosphorus (P) or Arsenic (As)) are implanted into semiconductor substrate 100 using a self-aligned ion implantation mask formed on the gate region to thereby form a source region 154 and a drain region 152 each having a conductivity type opposite that of semiconductor substrate 100.

Subsequently, a first interlayer insulation layer 102 is deposited on semiconductor substrate 100, on which the transistor is formed. First interlayer insulation layer 102 may be formed from SiO₂ or SiON. A plurality of contact holes 105 are then formed in first interlayer insulation layer 102 through performing a photoetching process on first interlayer insulation layer 102 to expose source region 154 and drain region 152. The plurality of contact holes 105 comprises direct contact hole 104 that exposes drain region 152 and buried contact hole 103 that exposes source region 154. Contact holes 105 are then filled with conductive material such as polysilicon to form a buried contact 106 in buried contact hole 103 and a direct contact 108 in direct contact hole 104. Buried contact 106 is adapted to electrically connect a lower electrode of a capacitor 130 (see FIG. 3F) to source region 154, and direct contact 108 (once it is formed into direct contact 108-1 (see FIG. 3F)) is adapted to electrically connect a bit line 122 (see FIG. 3F) to drain region 152.

Referring to FIG. 3B, a second interlayer insulation layer 110 is deposited on semiconductor substrate 100, on which buried contacts 106 and direct contacts 108 are formed. Second interlayer insulation layer 110 may be formed from SiO₂ or SiON.

Subsequently, a photosensitive layer is formed on second interlayer insulation layer 110 to cover second interlayer insulation layer 110. A photosensitive layer mask 112 is formed as shown in FIG. 3B by selectively removing, through exposure and development, portions of the photosensitive layer that are disposed on direct contacts 108.

Referring to FIG. 3C, an etching process using plasma is performed on semiconductor substrate 100, on which photosensitive layer mask 112 is formed. The etching process is a dry etching process that removes the portions of second interlayer insulation layer 110 that are exposed by photosensitive layer mask 112 and exposes direct contact 108. Subsequently, direct contact 108, which is exposed by the removal of portions of second interlayer insulation layer 110, is etched to a required depth through the dry etching process to thereby form a direct contact 108-1 that is smaller than direct contact 108 (as measured along a first dimension substantially perpendicular to a working surface of semiconductor substrate 100). Thus, an opening 116 that extends from an area substantially level with an upper surface of second interlayer insulation layer 110 to an upper surface of direct contact 108-1 is formed through the dry etching process. As used herein, the “thickness” of an element is the size of the element along a first dimension substantially perpendicular to a working surface of the corresponding semiconductor substrate. Also, as used herein, the term “thinner” relates to the thickness of an element, as defined previously.

Thus, direct contact 108-1 is formed such that the upper surface of direct contact 108-1 is disposed lower than the upper surface of buried contact 106 by a margin 140 by performing the dry etching process on direct contact 108 and not buried contact 106 by using photosensitive layer mask 112 in the dry etching process. That is, direct contact 108-1 is formed such that there is a step difference equal to margin 140 between the upper surface of direct contact 108-1 and the upper surface of buried contact 106. Forming direct contact 108-1 and buried contact 106 such that they have different heights substantially prevents a bridge from being formed between direct contact 108-1 and buried contact 106. Further, even if a bridge is formed between direct and buried contacts 108 and 106 during a process for forming direct and buried contacts 108 and 106, the bridge can be eliminated (i.e., cut off) during a process for etching direct contact 108 to form direct contact 108-1 to eliminate any problem that may be caused by a bridge formed between direct and buried contacts 108 and 106. As used herein, the term “lower” means relatively nearer the working surface of a corresponding semiconductor substrate along a dimension substantially perpendicular to the working surface of the corresponding semiconductor substrate, and the term “higher” means relatively further from the working surface of a corresponding semiconductor substrate along a dimension substantially perpendicular to the working surface of the corresponding semiconductor substrate. In addition, as used herein, the term “height” means the distance of the upper surface of an element from the working surface of a corresponding semiconductor substrate along a dimension substantially perpendicular to the working surface of the corresponding semiconductor substrate.

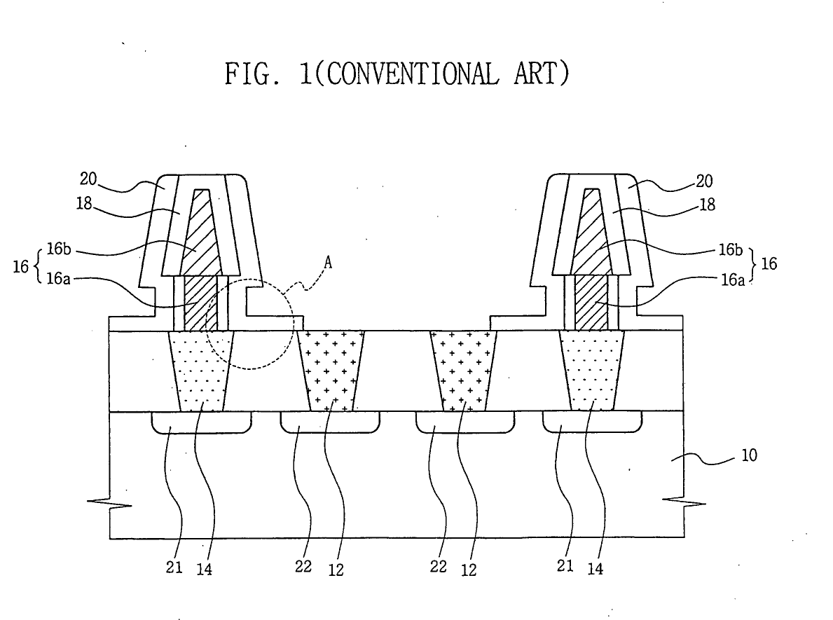

In addition, a bit line 122 will subsequently be formed on the upper surface of direct contact 108-1, which is lower than an upper surface of direct contact 108, so the bit line is effectively lowered (i.e., brought nearer the working surface of semiconductor substrate 100) by an amount equal to margin 140 relative to the conventional DRAM device of FIG. 1. In the context of photoetching processes, the “higher” (i.e., the relative vertical disposition) the position of a particular pattern in a memory device, the lower it resolution. Thus, in accordance with the embodiment illustrated in FIGS. 2 and 3, bit line 122, which is lowered by an amount equal to margin 140, does not adversely affect the resolution of a subsequent photoetching process for forming patterns.

Referring to FIGS. 3C, 3D, and 3E, after forming opening 116, photosensitive layer mask 112 is removed through an ashing and stripping process. An insulation layer 118 is then deposited on semiconductor substrate 100. Insulation layer 118 is formed in order to subsequently form a spacer 120 in opening 116 from insulation layer 118, and insulation layer 118 may be formed from silicon nitride (SiN), for example. In order to lengthen spacer 120 along a dimension substantially perpendicular to the working surface of semiconductor substrate 100, another insulation layer formed from a substance such as SiO₂ or SiON may also be formed on semiconductor substrate 100, on which buried contact 106 and direct contact 108-1 are formed.

Referring to FIG. 3E, spacer 120 is formed in opening 116 by performing an isotropic etching process on insulation layer 118. Next, a conductive layer is deposited on semiconductor substrate 100, on which spacer 120 is formed. Thus, conductive material is deposited on first interlayer insulation layer 110 and fills opening 116.

Next, a bit line 122 is formed by performing a typical photoetching process such that the conductive layer remains only on direct contact 108-1 and a portions of spacer 120. Bit line 122 is electrically connected to the drain region of the transistor through direct contact 108-1, so bit line 122 functions as a signal line adapted to input/output data of memory cells. In addition, a first insulation layer 124 is formed on an upper surface and sides of bit line 122. First insulation layer 124 may be formed from silicon nitride.

The conductive layer used to form bit line 122 may be formed from tungsten. Alternatively, bit line 122 may be formed through an alternative method in order to improve the speed of the semiconductor memory device. In the alternative method, a titanium silicide layer and a titanium nitride layer are each deposited in turn on semiconductor substrate 100, on which spacer 120 is formed, in order to form a barrier layer. A tungsten layer is then deposited on semiconductor substrate 100, on which the barrier layer is formed. The titanium silicide layer, the titanium nitride layer, and the tungsten layer are then patterned to form bit line 122.

As shown in FIGS. 3D and 3E, bit line 122 is formed by filling opening 116 with a conductive material after forming spacer 120 in opening 116. When, as described above, bit line 122 is formed in opening 116, in which spacer 120 is disposed, bit line 122 and buried contact 106 are insulated from one another (i.e., blocked) by spacer 120, which is formed from insulation material.

Thus, the problem of electrical short circuits occurring between a bit line and a buried contact, which frequently occurred in a conventional device in an area corresponding to the area indicated by reference symbol C of FIG. 3E, can be substantially eliminated. In addition, when bit line 122 is formed on direct contact 108-1 in accordance with an embodiment of the invention, bit line 122 can be formed through a single photoetching process, as opposed to the conventional art, in which a bit line is formed through forming a lower bit line and an upper bit line through two photoetching processes.

Referring to FIGS. 3E and 3F, second interlayer insulation layer 110 is removed after forming bit line 122, as described above. Second interlayer insulation layer 110 can be removed through a wet etching process using etchant having an etching selectivity between second interlayer insulation layer 110 and each of first insulation layer 124 and spacer 120, which may each be formed from silicon nitride.

Subsequently, a silicon nitride layer adapted to electrically isolate bit line 122 from peripheral structures is deposited on semiconductor substrate 100. A second insulation layer 126 is then formed on sidewalls of bit line 122 by performing an anisotropic etching process on the silicon nitride layer. A third interlayer insulation layer 128, formed from a substance such as SiO₂ or SiON, is then deposited on semiconductor substrate 100, on which bit line 122 is formed. Next, a lower electrode of a capacitor 130 that is electrically connected to source region 154 is formed on buried contact 106 through performing a photoetching process on third interlayer insulation layer 128.

In accordance with an embodiment of the invention, forming a spacer in the opening formed by etching a direct contact and thereby lowering an upper surface of the direct contact can substantially prevent electrical short circuits from occurring between a bit line and a buried contact in a semiconductor memory device. In addition, etching the direct contact such that the upper surface of the direct contact is lower than an upper surface of the buried contact can substantially prevent the formation of a bridge between the direct contact and the buried contact.

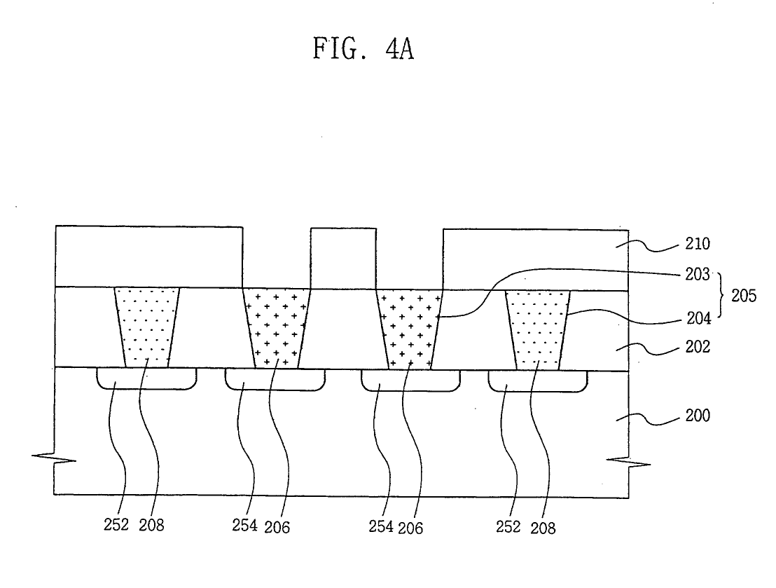

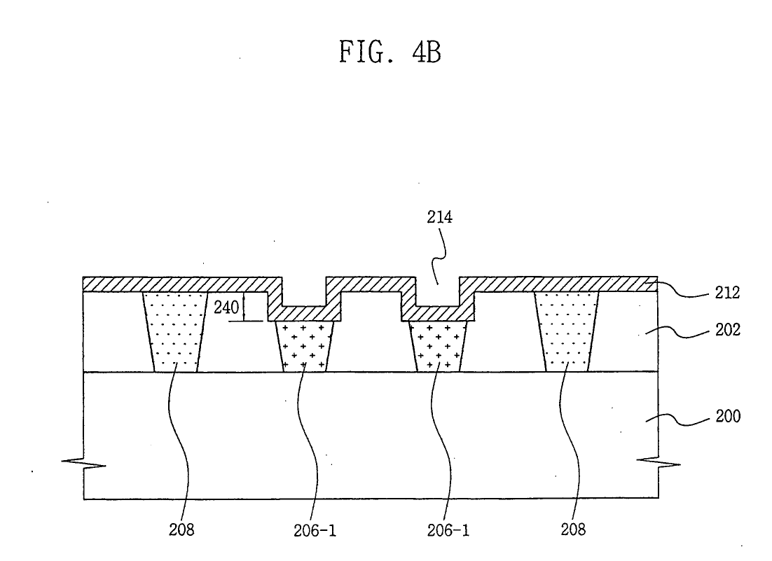

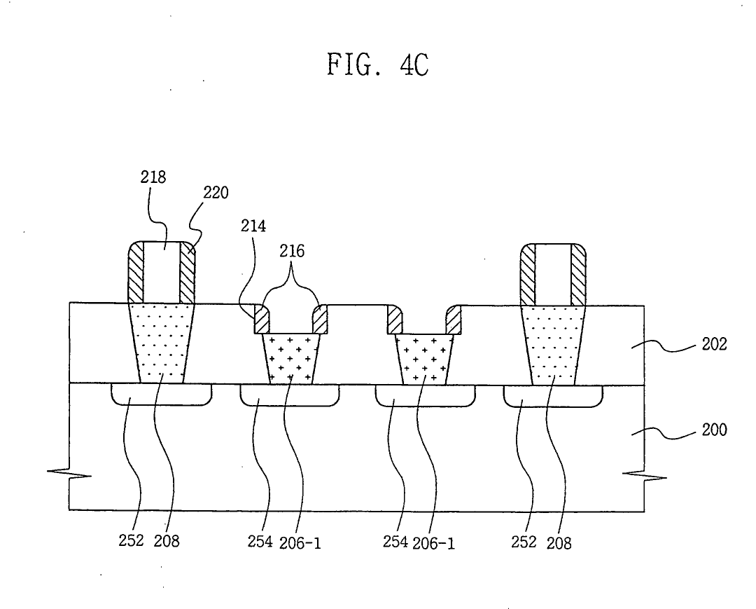

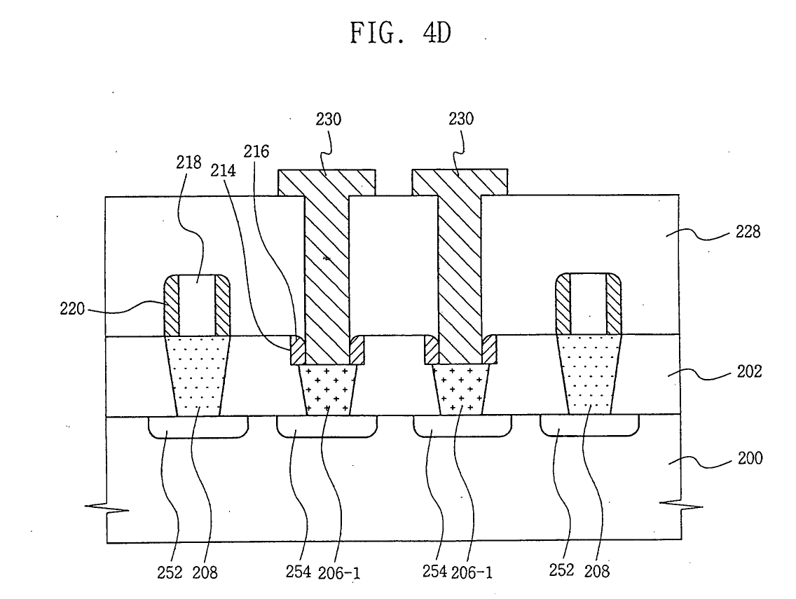

FIGS. 4A through 4D show a method for fabricating a semiconductor memory device in accordance with an embodiment of the invention. The method illustrated in FIGS. 4A through 4D is similar to the method for fabricating the semiconductor memory device of FIG. 2 described above with reference to FIGS. 3A through 3C, except for the process for forming the step difference between a direct contact 208 and a buried contact 206-1 in the embodiment illustrated in FIGS. 4A through 4D.

Referring first to FIG. 4A, a device isolation layer, such as an STI, is formed in a P-type (or N-type) semiconductor substrate 200 to define a field region and an active region. In order to form a transistor on the active region, a gate oxide layer, a conductive layer (such as a polysilicon), and a spacer are formed in turn in order to form a typical gate region. In addition, impurity ions of Group IIIA (e.g., boron (B)) or Group VA (e.g., phosphorus (P) or Arsenic (As)) are implanted into semiconductor substrate 200 using a self-aligned ion implantation mask formed on the gate region to thereby form a source region 254 and a drain region 252 each having a conductivity type opposite that of semiconductor substrate 200.

Subsequently, a first interlayer insulation layer 202 is deposited on semiconductor substrate 200, on which the transistor is formed. First interlayer insulation layer 202 may be formed from SiO₂ or SiON. A plurality of contact holes 205 are then formed in first interlayer insulation layer 202 through performing a photoetching process on first interlayer insulation layer 202 to expose source region 254 and drain region 252. The plurality of contact holes 205 comprises direct contact hole 204 that exposes drain region 252 and buried contact hole 203 that exposes source region 254. Contact holes 205 are then filled with conductive material such as polysilicon to form a buried contact 206 in buried contact hole 203 and a direct contact 208 in direct contact hole 204. Buried contact 206 is adapted to electrically connect a lower electrode of a capacitor 203 (see FIG. 4D) to source region 254 (after being formed into buried contact 206-1 (see FIG. 4D)), and direct contact 208 is adapted to electrically connect a bit line 218 to drain region 252.

Referring again to FIG. 4A, after forming buried contact 206 and direct contact 208, a photosensitive layer is formed on semiconductor substrate 200, on which buried contact 206 and direct contact 208 are formed. Next, a photosensitive layer mask 210, which exposes only buried contact 206, is formed through performing an exposure and development process on the photosensitive layer.

Referring to FIG. 4B, a dry etching process using plasma, etc., is performed on semiconductor substrate 200, on which photosensitive layer mask 210 is formed, in order to etch exposed buried contact 206 down to the required thickness. Thus, buried contact 206 is etched into a thinner buried contact 206-1 to form a step difference (i.e., a height difference) equal to a margin 240 between an upper surface of buried contact 206-1 and an upper surface of direct contact 208. In addition, an opening 214, which extends from an area substantially level with an upper surface of first interlayer insulation layer 202 to the upper surface of buried contact 206-1, is formed through the dry etching process.

After performing the etching process for forming buried contact 206-1, photosensitive layer mask 210 is removed through a typical ashing and stripping process. An insulation layer 212 is then deposited on semiconductor substrate 200. Insulation layer 212 is formed in order to subsequently form a spacer 216 in opening 214 from insulation layer 212 (see FIG. 4C). Subsequently, after forming a lower electrode of a capacitor 230, spacer 216 will be disposed adjacent to a sidewall of the lower electrode of the capacitor 230 (see FIG. 4D) and adapted to insulate the lower electrode of the capacitor 230 from a peripheral region (which may comprise direct contact 208 or bit line 218). In addition, insulation layer 212 may be formed from silicon nitride. In order to lengthen spacer 216 along a dimension substantially perpendicular to the working surface of semiconductor substrate 200, another insulation layer formed from a substance such as SiO₂ or SiON may also be formed on semiconductor substrate 200, on which buried contact 206-1 and direct contact 208 are formed.

Referring to FIGS. 4B and 4C, a spacer 216 is formed in opening 214 through performing an isotropic etching process on insulation layer 212. Next, a conductive layer is deposited on semiconductor substrate 200, on which spacer 216 is formed. In addition, a photoetching process is performed on the deposited conductive layer to form a bit line 218 electrically connected to direct contact 208. Bit line 218 may be formed from tungsten. Alternatively, bit line 218 may be formed through an alternative method in order to improve the speed of the semiconductor memory device. In the alternative method, a titanium silicide layer and a titanium nitride layer are formed on semiconductor substrate 200 to form a barrier layer, and a tungsten layer is formed on the barrier layer. The titanium silicide layer, the titanium nitride layer, and the tungsten layer are then patterned to form bit line 218. Next, an insulation layer 220 is formed on a sidewall of bit line 218.

Referring to FIG. 4D, a second interlayer insulation layer 228, formed from a substance such as SiO₂ or SiON, is then deposited on semiconductor substrate 200, on which bit line 218 is formed. Next, a lower electrode of a capacitor 230 is formed on buried contact 206-1 and thereby electrically connected to source region 254. In addition, spacer 216 is disposed adjacent to a sidewall of lower electrode of a capacitor 230, and the spacer is adapted to insulate the lower electrode of the capacitor from a peripheral region.

In the embodiment described above with reference to FIGS. 4A through 4D, a dry etching process is performed on buried contact 206 (and not direct contact 208) to form buried contact 206-1 such that there is a step difference equal to a margin 240 between the upper surface of buried contact 206-1 and the upper surface of direct contact 208. The step difference substantially prevents a bridge from forming between direct contact 208 and buried contact 206-1. Further, even if a bridge is formed during a process for forming buried and direct contacts 206 and 208, the bridge can be eliminated (i.e., cut off) during a process for etching buried contact 206 to form buried contact 206-1 to eliminate any problem that may be caused by the bridge formed between buried and direct contacts 206 and 208. In addition, since bit line 218 is formed on direct contact 208, which has a higher upper surface than buried contact 206-1, an electrical short circuit between buried contact 206-1 and bit line 218 can also be substantially prevented.

Although embodiments of the invention have been described herein, various modifications and alternative arrangements within the capabilities of a person skilled in the art may be made to the embodiments without departing from the scope of the invention as defined by the accompanying claims.

What is claimed is:

1. A semiconductor memory device comprising:
source and drain regions disposed in a semiconductor substrate;
a buried contact disposed on and electrically connected to the source region;
a direct contact disposed on and electrically connected to the drain region, wherein an upper surface of the direct contact is disposed at a different height than an upper surface of the buried contact;
a bit line disposed on and electrically connected to the direct contact; and,
a lower electrode of a capacitor disposed on and electrically connected to the buried contact.

2. The device of claim 1, wherein:
the buried contact and the direct contact are each disposed in an interlayer insulation layer; and,
the upper surface of the direct contact is disposed lower than the upper surface of the buried contact.

3. The device of claim 2, further comprising an outer insulation layer disposed on the bit line and adapted to insulate the bit line from a peripheral region.

4. The device of claim 3, wherein the peripheral region comprises the buried contact or the lower electrode of the capacitor.

5. The device of claim 4, wherein the insulation layer comprises:
a spacer disposed adjacent to a lower sidewall of the bit line;
a first insulation layer disposed on the spacer and adjacent to an upper sidewall of the bit line; and,
a second insulation layer disposed adjacent to a sidewall of the first insulation layer and a portion of a sidewall of the spacer.

6. The device of claim 1, wherein:
the buried contact and the direct contact are each disposed in an interlayer insulation layer; and,
the upper surface of the direct contact is disposed higher than the upper surface of the buried contact.

7. The device of claim 6, further comprising a spacer disposed adjacent to a sidewall of the lower electrode of the capacitor, wherein the spacer is adapted to insulate the lower electrode of the capacitor from a peripheral region.

8. The device of claim 7, wherein the peripheral region comprises the direct contact or the bit line.

9. A method for fabricating a semiconductor memory device comprising:
forming source and drain regions in a semiconductor substrate;
depositing a first interlayer insulation layer on the semiconductor substrate;
forming plurality of contact holes comprising a buried contact hole and a direct contact hole in the first interlayer insulation layer, wherein the buried contact hole exposes the source region and the direct contact hole exposes the drain region;
filling the contact holes with a first conductive material to form a buried contact electrically connected to the source region and a direct contact electrically connected to the drain region;
selectively etching the direct contact to reduce the height of an upper surface of the direct contact and to thereby form an opening;
forming a spacer on a sidewall of the opening;
filling the opening with at least one second conductive material;
patterning the at least one second conductive material to form a bit line connected to the drain region through the direct contact, wherein the spacer is adapted to insulate the bit line from a peripheral region;
depositing a second interlayer insulation layer on the semiconductor substrate after forming the bit line; and,
forming a lower electrode of a capacitor on the semiconductor substrate, wherein the lower electrode of the capacitor is electrically connected to the source region through the buried contact.

10. The method of claim 9, wherein the first conductive material is polysilicon and the at least one second conductive material is tungsten.

11. The method of claim 9, wherein the upper surface of the direct contact is disposed lower than the upper surface of the buried contact after selectively etching the direct contact.

12. The method of claim 9, wherein the first interlayer insulation layer and the second interlayer insulation layer are formed from SiO₂ or SiON.

13. The method of claim 12, wherein the peripheral region comprises the buried contact or the lower electrode of the capacitor.

14. The method of claim 13, wherein the spacer is formed from SiN.

15. The method of claim 14, wherein filling the opening with at least one second conductive material comprises forming a titanium silicide layer, a titanium nitride layer, and a tungsten layer on the semiconductor substrate.

16. A method for fabricating a semiconductor memory device comprising:
forming source and drain regions in a semiconductor substrate;
depositing a first interlayer insulation layer on the semiconductor substrate;
forming a plurality of contact holes comprising a buried contact hole and a direct contact hole in the interlayer insulation layer, wherein the buried contact hole exposes the source region and the direct contact hole exposes the drain region;
filling the contact holes with a first conductive material to form a buried contact electrically connected to the source region and a direct contact electrically connected to the drain region;
selectively etching the buried contact to reduce the height of an upper surface of the buried contact and to thereby form an opening, wherein an upper surface of the direct contact is disposed higher than the upper surface of the buried contact after selectively etching the buried contact;
forming a spacer on a sidewall of the opening;
forming a bit line on and electrically connected to the direct contact;
depositing a second interlayer insulation layer on the semiconductor substrate after forming the bit line; and,
forming a lower electrode of a capacitor on the semiconductor substrate, wherein the lower electrode of the capacitor is electrically connected to the source region through the buried contact, and the spacer is adapted to insulate the lower electrode of the capacitor from a peripheral region.

17. The method of claim 16, wherein the first conductive material is polysilicon.

18. The method of claim 16, wherein the first interlayer insulation layer and the second interlayer insulation layer are formed from SiO₂ or SiON.

19. The method of claim 18, wherein the peripheral region comprises the direct contact or the bit line.

20. The method of claim 19, wherein the spacer formed from SiN.
